(19) United States
(12) Patent Application Publication
(10) Pub. No.: US 2009/0081814 A1
(43) Pub. Date: Mar. 26, 2009

(54) INTEGRATED MANUFACTURING SYSTEM WITH TRANSISTOR DRIVE CURRENT CONTROL

(75) Inventors: Ming Lei, Singapore (SG); Ricky Seet, Singapore (SG); Young Tai Kim, Ichon-City (KR); Lieyong Yang, Singapore (SG); Chee Kong Leong, Singapore (SG); Sean Lian, Singapore (SG)

Correspondence Address: LAW OFFICES OF MIKIO ISHIMARU, 333 W. EL CAMINO REAL, SUITE 330, SUNNYVALE, CA, 94087, US

(73) Assignee: CHARTERED SEMICONDUCTOR MANUFACTURING LTD., Singapore (SG)

(21) Appl. No.: 11/861,587

(22) Filed: Sep. 26, 2007

(51) Int. Cl. H01L 21/66

(52) U.S. Cl. 438/7; 257/E21.53

(57) ABSTRACT

An integrated manufacturing system comprising: providing a substrate; forming a gate over the substrate; measuring a gate length of the gate; forming a first spacer adjacent the gate; measuring a spacer critical dimension of the spacer; and adjusting a dose of an implant based on the gate length and the spacer critical dimension for a source/drain region.

### TECHNICAL FIELD

The present invention relates generally to integrated manufacturing systems and more particularly to a system for integrated manufacturing with transistors drive current control.

### BACKGROUND ART

Integrated circuits have become very common in many products, such as cell phones, portable computers, voice recorders, cars, planes, industrial control systems, etc. For all of these products, consumers demand smaller size, more features, and higher performance. The continued demand for improved size, features, and performance is particularly noticeable in portable electronics.

Virtually all electronic products benefit from increasing features (including functions and performance) in integrated circuit chips all while being designed into ever smaller physical space. These demands are often very visible with the many consumer electronic products including but not limited to personal portable devices, such as cellular phones, digital cameras, and music players.

Thus, there is a constant drive within the semiconductor industry to increase the quality, reliability, and throughput of integrated circuit devices, e.g., microprocessors, memory devices, and the like. This drive is fueled by consumer demands for higher quality computers and electronic devices that operate more reliably.

These demands have resulted in a continual improvement in the manufacture of semiconductor devices, e.g., transistors, as well as in the manufacture of integrated circuit devices incorporating such transistors. Additionally, reducing defects in the manufacture of the components of a typical transistor also lowers the overall cost per transistor as well as the cost of integrated circuit devices incorporating such transistors.

The technologies underlying semiconductor processing tools have attracted increased attention over the last several years, resulting in substantial refinements. However, despite the advances made in this area, many of the processing tools that are currently commercially available suffer certain deficiencies. In particular, such tools often lack advanced process data monitoring capabilities, such as the ability to provide historical parametric data in a user-friendly format, as well as event logging, real-time graphical display of both current processing parameters and the processing parameters of the entire run, and remote, i.e., local site and worldwide, monitoring.

These deficiencies can engender nonoptimal control of critical processing parameters, such as throughput accuracy, stability and repeatability, processing temperatures, mechanical tool parameters, and the like. This variability manifests itself as within-run disparities, run-to-run disparities and tool-to-tool disparities that can propagate into deviations in product quality and performance, whereas an ideal monitoring and diagnostics system for such tools would provide a means of monitoring this variability, as well as providing means for optimizing control of critical parameters.

Among the parameters it would be useful to monitor and control are critical dimensions (CDs) and doping levels for transistors (and other semiconductor devices), as well as overlay errors in photolithography. CDs are the smallest feature sizes that particular processing devices may be capable of producing. For example, the minimum widths of polysilicon or poly gate lines for metal-oxide semiconductor field-effect-transistors (MOSFETs) may correspond to one critical dimension (CD) for a semiconductor device having such transistors.

Similarly, the junction depth below the surface of a doped substrate to the bottom of a heavily doped source/drain region formed within the doped substrate may be another critical dimension (CD) for a semiconductor device such as an MOS transistor. Doping levels may depend on dosages of ions implanted into the semiconductor devices.

However, traditional statistical process control (SPC) techniques are often inadequate to control precisely CDs and doping levels in semiconductor and microelectronic device manufacturing to optimize device performance and yield. Typically, SPC techniques set a target value, and a spread about the target value, for the CDs, doping levels, and/or overlay errors in photolithography

As transistor dimensions continue shrinking to 90 nm technology nodes and below, spacer widths becomes significant particularly with respect to device performance. Conventional manufacturing processes and controls are no longer sufficient for precise control of the transistor drive current or Ion.

Despite the advantages of recent developments in integrated circuit fabrication there is a continuing need for improving manufacturing control and integrated circuit performance.

Thus, a need still remains for an integrated manufacturing system to provide improved control of manufacturing process including implant doses for Ion control. In view of the increasing demand for improved density of integrated circuits and particularly portable electronic products, it is increasingly critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a substrate; forming a gate over the substrate; measuring a gate length of the gate; forming a first spacer adjacent the gate; measuring a spacer critical dimension of the spacer; and adjusting a dose of an implant based on the gate length and the spacer critical dimension for a source/drain region.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated manufacturing system taken along line 1-1 of FIG. 2 in a first embodiment of the present invention;

FIG. 2 is a top view of the integrated manufacturing system;

FIG. 3 is a cross-sectional view of the integrated manufacturing system in a gate forming phase;

FIG. 4 is a cross-sectional view of the integrated manufacturing system in a spacer forming phase;

FIG. 5 is a cross-sectional view of the integrated manufacturing system in a source/drain extension implanting phase;

FIG. 6 is a cross-sectional view of the integrated manufacturing system in another spacer forming phase;

FIG. 7 is a cross-sectional view of the integrated manufacturing system in a source/drain implanting phase;

FIG. 8 is a cross-sectional view of the integrated manufacturing system in a dopant activating phase;

FIG. 9 is a cross-sectional view of an Advanced Process Control System that can be applied to the integrated manufacturing system; and

FIG. 10 is a flow chart of an integrated manufacturing system for manufacturing the integrated manufacturing system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs.

Where multiple embodiments are disclosed and described, having some features in common, for clarity and ease of illustration, description, and comprehension thereof, similar and like features one to another will ordinarily be described with like reference numerals. The embodiments may be numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the invention, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “on” as used herein means and refers to direct contact among elements. The term “processing” as used herein includes deposition of material, patterning, exposure, development, etching, cleaning, and/or removal of the material or trimming as required in forming a described structure. The term “system” as used herein means and refers to the method and to the apparatus of the present invention in accordance with the context in which the term is used.

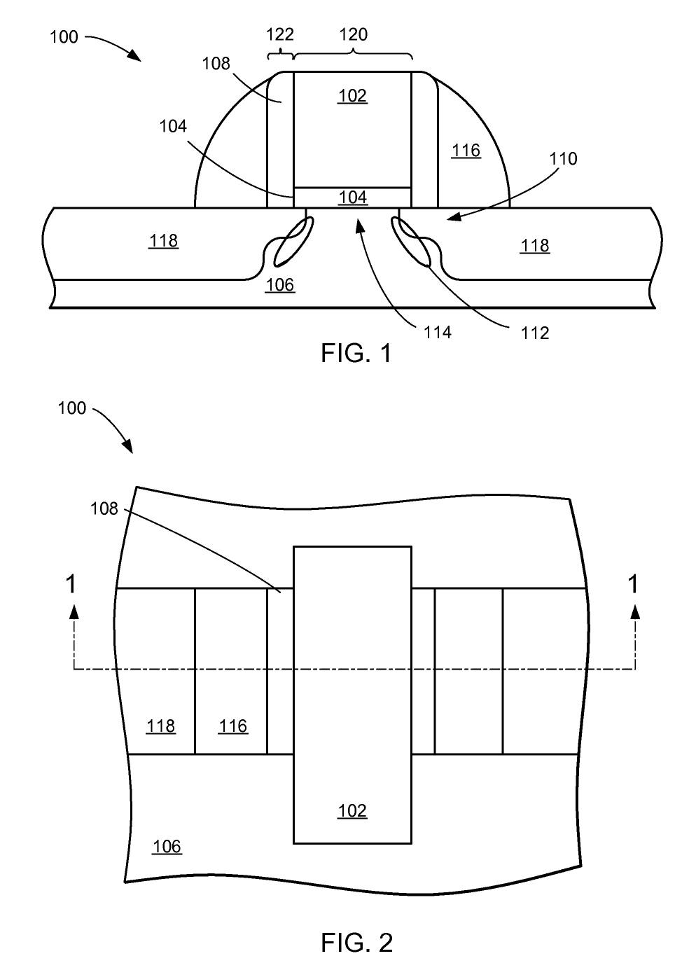

Referring now to FIG. 1, therein is shown a cross-sectional view of an integrated manufacturing system 100 taken along line 1-1 of FIG. 2 in a first embodiment of the present invention. The integrated manufacturing system 100 preferably includes a gate 102 formed over a gate dielectric 104 and a substrate 106.

A first spacer 108 can be formed adjacent opposite sides of the gate 102 and the gate dielectric 104. The first spacer 108 can be formed from a thin dielectric film, such as an oxide, a nitride, or an oxide-nitride dual stack, deposited over the substrate 106 and etched back.

The substrate 106 can include source/drain extension regions 110 preferably formed with source/drain extension implants and source/drain implants.

For certain devices, the substrate 106 can include optional halo implants, such as pocket implants or implants directed at the wafer at acute angles, providing halo regions 112 formed near the source/drain extension regions 110 and a channel region 114 of the substrate 106. The halo regions 112 can reduce sub threshold leakage through the channel region 114 and the source/drain extension regions 110.

A second spacer 116 can be formed adjacent the first spacer 108 on opposite sides of the gate 102 and the gate dielectric 104. The second spacer 116 can be formed from etching back one or more layers of dielectric film deposited over the gate 102, the first spacer 108, and the substrate 106.

Source/drain implants can be applied over the gate 102, the first spacer 108, the second spacer 116, and the source/drain extension regions 110, to form source/drain regions 118. The source/drain regions 118 can be formed in the substrate 106 adjacent the source/drain extension regions 110, the halo regions 112 or the channel region 114.

The source/drain implants, the source/drain extension implants, or the halo implants can preferably be adjusted based on an Ion control model utilizing a gate length 120 and a spacer critical dimension 122. Ion control can be provided by adjusting the source/drain extension, halo, or both implant doses based on the gate length 120 and the spacer critical dimension 122.

It has been discovered that the integrated manufacturing system 100 with the transistor Ion control provides significantly more accurate Ion control resulting in significantly improved performance.

Referring now to FIG. 2 therein is shown a top view of the integrated manufacturing system 100. The integrated manufacturing system 100 preferably includes the substrate 106 having the source/drain regions 118. The second spacer 116 is preferably formed adjacent outer edges of the first spacer 108 on the outer edge opposite the gate 102. The first spacer 108 is preferably formed adjacent opposite outer edges of the gate 102. The gate 102, the second spacer, and the first spacer are formed over the substrate 106.

For illustrative purposes, the integrated manufacturing system 100 is shown having one device although it is understood that any number of devices or interconnect may be used.

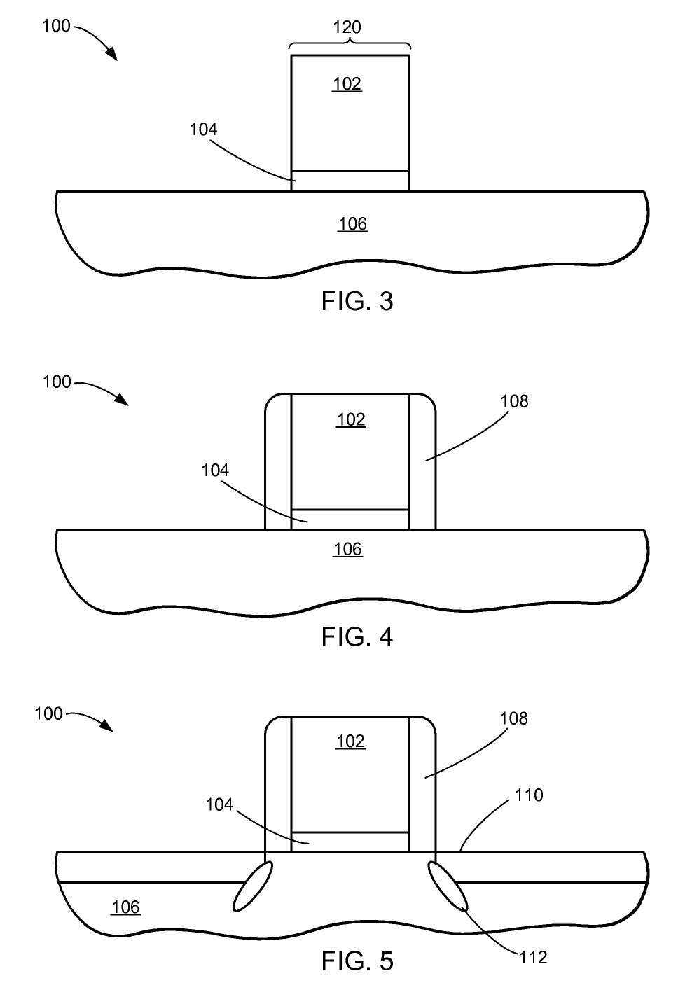

Referring now to FIG. 3, therein is shown a cross-sectional view of the integrated manufacturing system 100 in a gate forming phase. The integrated manufacturing system 100 preferably includes the gate dielectric 104 formed over the substrate 106. The gate 102 is preferably formed over the gate dielectric 104. The gate 102 has a dimension typically referred to as the gate length 120.

Referring now to FIG. 4, therein is shown a cross-sectional view of the integrated manufacturing system 100 in a spacer forming phase. The integrated manufacturing system 100 preferably includes the structure of FIG. 3. Additionally, the first spacer 108 can preferably be formed adjacent the gate 102 and the gate dielectric 104.

Referring now to FIG. 5, therein is shown a cross-sectional view of the integrated manufacturing system 100 in a source/drain extension implanting phase. The integrated manufacturing system 100 preferably includes the structure of FIG. 4. Additionally, the source/drain extension regions 110 and the halo regions 112 are formed in the substrate 106.

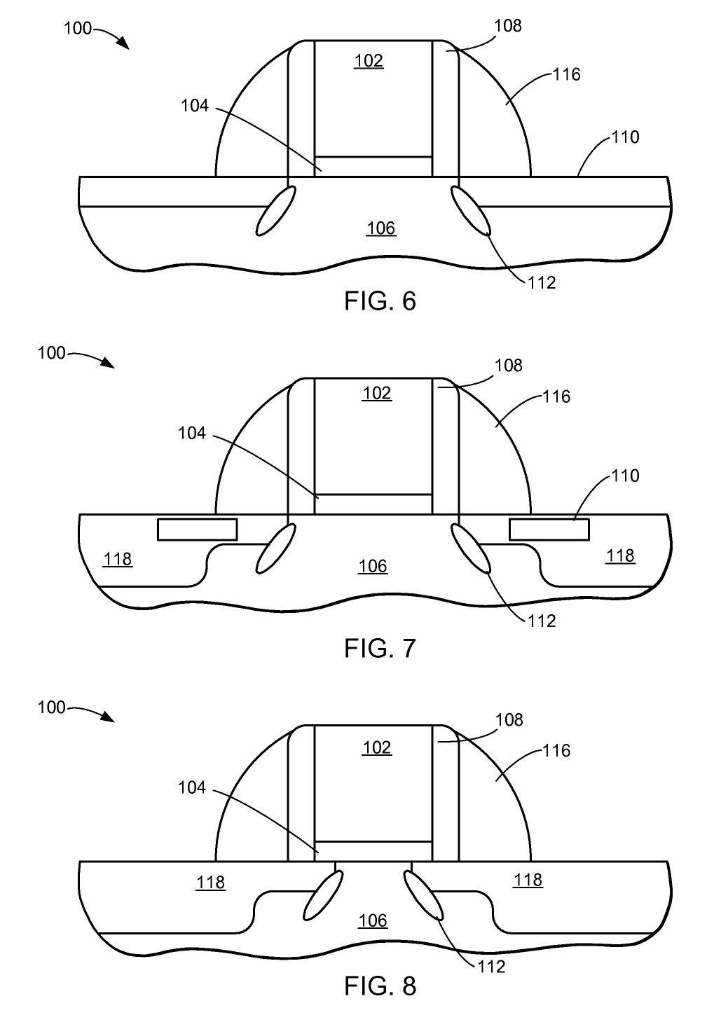

Referring now to FIG. 6, therein is shown a cross-sectional view of the integrated manufacturing system 100 in another spacer forming phase. The integrated manufacturing system 100 preferably includes the structure of FIG. 5. Additionally, the second spacer 116 can preferably be formed adjacent the outer edges of the first spacer 108 opposite the gate 102.

Referring now to FIG. 7, therein is shown a cross-sectional view of the integrated manufacturing system 100 in a source/drain implanting phase. The integrated manufacturing system 100 preferably includes the structure of FIG. 6. Additionally, the source/drain regions 118 can preferably be formed in the substrate 106 adjacent the halo regions 112.

Referring now to FIG. 8, therein is shown a cross-sectional view of the integrated manufacturing system 100 in a dopant activating phase. The integrated manufacturing system 100 preferably includes the structure of FIG. 7. The source/drain regions 118 can be activated and driven in to the substrate 106 by manufacturing processes such as annealing.

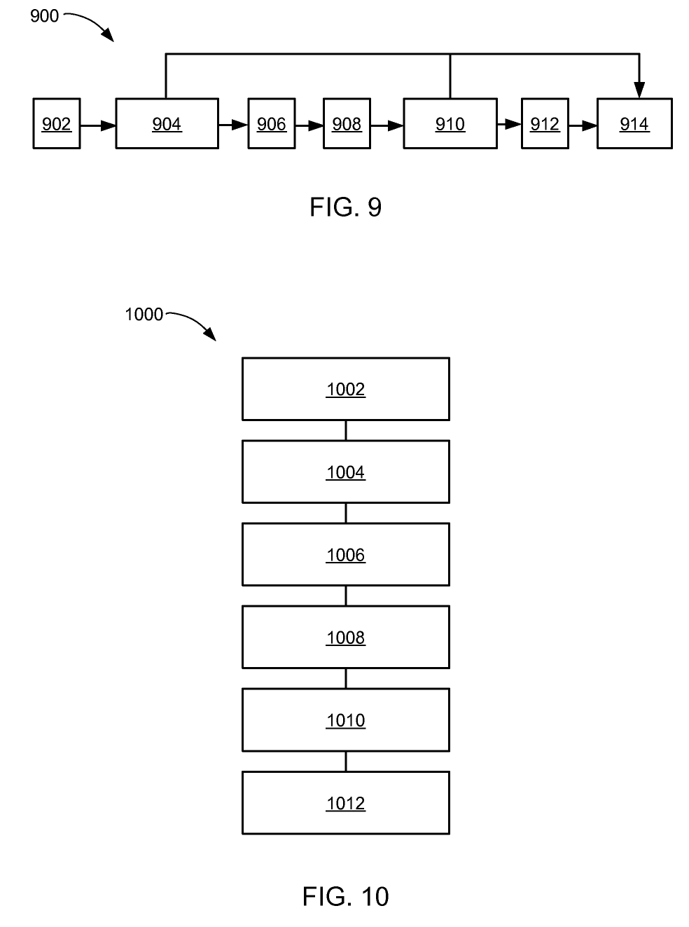

Referring now to FIG. 9, therein is shown an Advanced Process Control System 900 that can be applied to the integrated manufacturing system 100. The Advanced Process Control System 900 preferably includes a poly etch process in a block 902. A poly critical dimension measurement can be performed in a block 904. Process between gate and spacer formation can be performed in a block 906. Manufacturing processes including a spacer forming processes can be performed in a block 908. Measurement of the first spacer 108 of FIG. 1 can be performed in a block 910. Processes between spacer formation and S/D extension implantations can be performed in a block 912. Process control and manufacturing processes including adjusting implant dose can be performed in a block 914. Implanting the source/drain extension regions 110 of FIG. 1 or the halo regions 112 of FIG. 1 can be performed in a block 914.

Referring now to FIG. 10, therein is shown a flow chart of an integrated manufacturing system 1000 for manufacturing the integrated manufacturing system 100 in an embodiment of the present invention. The system 1000 includes providing a substrate in a block 1002; forming a gate over the substrate in a block 1004; measuring a gate length of the gate in a block 1006; forming a first spacer adjacent the gate in a block 1008; measuring a spacer critical dimension of the spacer in a block 1010; and adjusting a dose of an implant based on the gate length and the spacer critical dimension for a source/drain region in a block 1012.

In greater detail, a system to provide the method and apparatus of the integrated manufacturing system 100, in an embodiment of the present invention, is performed as follows:
1. Providing a substrate.
2. Forming a gate dielectric over the substrate.
3. Forming a gate over the gate dielectric.
4. Measuring a gate length of the gate.
5. Forming a first spacer adjacent the gate and the gate dielectric.
6. Measuring a spacer critical dimension of the spacer.
7. Adjusting a dose of an implant based on the gate length and the spacer critical dimension.
8. Forming a source/drain region with the dose of the implant.

Thus, it has been discovered that the integrated manufacturing system method and apparatus of the present invention furnish important and heretofore unknown and unavailable solutions, capabilities, and functional aspects. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated manufacturing system comprising:
providing a substrate;
forming a gate over the substrate;
measuring a gate length of the gate;
forming a first spacer adjacent the gate;
measuring a spacer critical dimension of the spacer; and
adjusting a dose of an implant based on the gate length and the spacer critical dimension for a source/drain region.

2. The system as claimed in claim 1 wherein adjusting the dose of the implant includes adjusting the source/drain region.

3. The system as claimed in claim 1 wherein adjusting the dose of the implant includes adjusting a source/drain extension region.

4. The system as claimed in claim 1 wherein adjusting the dose of the implant includes adjusting a halo region.

5. The system as claimed in claim 1 further comprising forming a second spacer adjacent the first spacer.

6. An integrated manufacturing system comprising:
providing a substrate;
forming a gate dielectric over the substrate;
forming a gate over the gate dielectric;
measuring a gate length of the gate;
forming a first spacer adjacent the gate and the gate dielectric;
measuring a spacer critical dimension of the spacer;
adjusting a dose of an implant based on the gate length and the spacer critical dimension; and
forming a source/drain region with the dose of the implant.

7. The system as claimed in claim 6 wherein adjusting the dose of the implant includes providing Ion control of the source/drain region.

8. The system as claimed in claim 6 wherein adjusting the dose of the implant includes providing Ion control of a source/drain extension region.

9. The system as claimed in claim 6 wherein adjusting the dose of the implant includes providing Ion control of a halo region.

10. The system as claimed in claim 6 further comprising forming a second spacer adjacent an outer edge of the first spacer on a side opposite the gate.

11. An integrated manufacturing system comprising:
a substrate;
a gate over the substrate;
a gate length of the gate of a predetermined length;
a first spacer formed adjacent the gate;
a spacer critical dimension of the spacer of a predetermined size; and
a dose of an implant based on the predetermined length and the predetermined size for a source/drain region.

12. The system as claimed in claim 11 wherein the dose of the implant includes an ion concentration of the source/drain region.

13. The system as claimed in claim 11 wherein the dose of the implant includes an ion concentration of source/drain extension region.

14. The system as claimed in claim 11 wherein the dose of the implant includes an ion concentration of a halo region.

15. The system as claimed in claim 11 further comprising a second spacer adjacent the first spacer.

16. The system as claimed in claim 11 wherein:
a substrate;
a gate dielectric over the substrate;
a gate over the gate dielectric;
a gate length of the gate of a predetermined length;
a first spacer adjacent the gate and the gate dielectric;
a spacer critical dimension of the spacer of a predetermined size;
a dose of an implant based on the predetermined length and the predetermined size; and
a source/drain region formed with the dose of the implant.

17. The system as claimed in claim 16 wherein the dose of the implant includes a predetermined ion concentration of the source/drain region.

18. The system as claimed in claim 16 wherein the dose of the implant includes a predetermined ion concentration of a source/drain extension region.

19. The system as claimed in claim 16 wherein the dose of the implant includes a predetermined ion concentration of a halo region.

20. The system as claimed in claim 16 further comprising a second spacer adjacent an outer edge of the first spacer on a side opposite the gate.
